(19) United States
(12) Patent Application Publication
(10) Pub. No.: US 2010/0089434 A1
(43) Pub. Date: Apr. 15, 2010

(54) Efficient Air-Cooled Solar Photovoltaic Modules and Collectors for High Power Applications

(76) Inventor: Oleg S. Fishman, Maple Glen, PA (US)

Correspondence Address: OLEG S FISHMAN, 1 SALJON COURT, MAPLE GLEN, PA, 19002, US

(21) Appl. No.: 12/434,642

(22) Filed: May 2, 2009

Related U.S. Application Data
(60) Provisional application No. 61/104,720, filed on Oct. 11, 2008.

(51) Int. Cl. H01L 31/042; B29C 65/02

(52) U.S. Cl. 136/246; 156/60

(57) ABSTRACT

A solar photovoltaic module is formed from a single linear, series-connected arrangement of solar cells on a linear mounting assembly or substrate that provides high heat dissipation from the photovoltaic module. Multiple photovoltaic modules are connected together to form a photovoltaic collector for high voltage applications with solar tracker mounting. High voltage photovoltaic collectors are interconnected to form a high power capacity photovoltaic power source for conversion to AC power.

### CROSS-REFERENCE TO RELATED APPLICATIONS

This application claims the benefit of U.S. Provisional Application No. 61/104,720, filed Oct. 11, 2008 hereby incorporated by reference in its entirety.

### FIELD OF THE INVENTION

The present invention relates to photovoltaic flat panel solar cell modules, assembly of such modules into photovoltaic collectors, and photovoltaic power collection circuits for high power applications.

### BACKGROUND OF THE INVENTION

A photovoltaic (PV) module, or solar module, is an integrally packaged, electrically interconnected, assembly of a plurality of solar cells. A plurality of PV modules 102 can be electrically interconnected to form a PV collector 104 as shown in FIG. 1. For large ground-mounted solar electric power collection sites, the total number of interconnected PV collectors making up a PV array can number in the thousands to form a solar farm (park) having a peak DC (direct current) power rating ranging from tens to hundreds of megawatts. For example, one design for a 50 MW rated solar farm comprises over 220,000 standard PV modules that also are used in small residential and medium size commercial applications. Consequently concepts that are not economically feasible for smaller installations of PV modules may be economically feasible for larger installations. For example PV collectors can be mounted on solar tracking mechanical apparatus (solar trackers) so that the sunlight incident on the solar cells in each collector is maximized as the earth rotates relative to the sun. The life cycle cost associated with tracking apparatus is not feasible for installations with relatively small quantities of PV modules since a relatively small increase in power output from each module achieved by tracking is multiplied by a small quantity of modules. However for installations with thousands of modules, the larger increase in total power output from all modules may be sufficient to offset life cycle costs of solar trackers. Table 1 illustrates typical increases in solar energy collection with PV collectors utilizing single axis trackers (annular sun tracking) and dual axis trackers (daily and annular sun tracking) over that achievable with fixed mount PV collectors.

TABLE 1
increase in solar energy collection utilizing trackers

| | | | Increase in | | |
|---|---|---|---|---|---|
| | | Single axis | energy | | Increase in |
| | | tracker | collection | | energy |
| Latitudinal | | annual | for single | Dual axis | collection for |
| location of | Fixed mount | solar | axis tracking | tracker annual | dual axis |
| PV | annual solar | energy | over fixed | solar energy | tracking over |
| collectors | energy collection | collection | mount | collection | fixed mount |
| (degrees) | (kW/m²) | (kW/m²) | (percent) | (kW/m²) | (percent) |
| 25 | 2,608 | 3,413 | 131 | 3558 | 136 |
| 30 | 2,555 | 3,346 | 131 | 3485 | 136 |
| 35 | 2,500 | 3,271 | 131 | 3412 | 136 |
| 40 | 2,415 | 3,167 | 131 | 3305 | 137 |
| 45 | 2,317 | 3,027 | 131 | 3160 | 136 |
| 50 | 2,194 | 2,869 | 131 | 2990 | 136 |
| 55 | 2,034 | 2,664 | 131 | 2784 | 137 |
| 60 | 1,830 | 2,404 | 131 | 2514 | 137 |

FIG. 2 diagrammatically represents three series stacks (106(a), 106(b) and 106(c)) of solar (PV) cells 106 that are used to form an array of solar cells in a typical PV module. The series stacks may comprise, for example, a total of 60 cells planarly arrayed in the PV module. Physically this particular arrangement of cells occupies a total planar area of around 1.6 square meters and can produce approximately 224 watts (32 DC volts and 7 amperes) of power when the cells are exposed to standard sunlight exposure (standard test conditions) of 1,000 watts per square meter of sun energy at 25 degrees Celsius. Typically a bypass diode 108 is connected in parallel with the cells making up the PV module to bypass the solar cells if they are not generating current when the cells are shadowed, or if the cells are not exposed to sufficient sunlight for any reason. The output voltage, V_{PVM}, of a module depends on the electrical load connected to the electrical output of the module and generally decreases as the amount of current drawn from the module increases.

FIG. 3 graphically illustrates the electrical performance characteristics of a PV module comprising the arrangement of cells shown in FIG. 2. In FIG. 3 there are a series of paired curves wherein each pair of curves represent the module's output current (in amperes) and power (in watts) relative to voltage (volts) for different magnitudes of sunlight exposure. In order of increasing sunlight exposure the paired curves are: 108(a) and 110(a); 108(b) and 110(b); 108(c) and 110(c); 108(d) and 110(d); and 108(e) and 110(e), where the solid lines represent output current performance and the dashed lines represent output power performance (where power is equal to voltage multiplied by current). Output voltage decreases as the load current increases. Output voltage decreases starting from open circuit voltage, V_{oc}. Output current reaches a maximum (short circuit current I_{sc}) when the output of the cells making up the PV module is shorted. Output power increases steadily with increasing current up to the maximum power point (MPP), which is defined by the intersection of line “MPP” with each power curve in FIG. 3, and then drops. Therefore optimum power output is achieved at the MPP, which is the desired operating point. The MPP is strongly dependent upon insolation. If sun energy incident on a PV module is degraded, for example, by clouds blocking the sun, or dust on the top of a PV module, as shown in FIG. 3, the MPP moves down and to the left. This represents reduced electrical power being produced by the PV module at a lower than optimum DC output voltage. In high capacity solar farms, a large number of PV modules are connected in series to achieve a high DC voltage across the total series connection, and multiples of these series connected groups of PV modules are connected in parallel to achieve a high DC current output. Each series connected group of PV modules is electrically isolated from the other series connected groups of PV modules by a blocking diode to prevent DC current from some of the series connected groups of PV modules operating at a lower voltage from being injected into the output of other series connected groups of PV modules operating at a higher voltage. Such reverse current flow through the degraded output series connected groups of PV modules can seriously degrade or destroy the solar cells making up the degraded group of modules. Also the higher DC voltage across the series connected groups of PV modules operating at, or near to, the MPP will be applied across the degraded output series connected groups of PV modules, which further decreases the total electrical output from the combination of optimum performance and degraded output series connected groups of PV modules. The decrease in efficiency can range from one to five percent from the efficiency achievable when each of the series connected groups of PV modules is operating at its MPP.

Each solar cell making up an array of solar cells in a PV module is represented by a semiconductor diode with a typical surface area of 0.156 by 0.156 square meters. Typical semiconductor material is wafer-based crystalline silicon, although other materials are also suitable. The wafer may be formed from monocrystalline or multi-crystalline silicon. The conversion efficiency of a monocrystalline silicon solar cell is typically 22 to 24 percent, while the conversion efficiency of a multi-crystalline silicon solar cell is usually about 14 to 16 percent. The wafer consists of two layers, p-type silicon and n-type silicon, with hole and electron electric charge carriers, forming a depleted p-n junction. Sunlight excites the charge carriers to cause them to migrate from the majority crystal structure to the conduction zone; that is electrons pass from the p-type layer to the n-type layer, and holes pass from the n-type layer to the p-type layer. Only photons from the sunlight having energy greater than the energy of the p-n junction energy band gap, E_{G}, as defined by the following equation, can create an electron-hole pair and contribute to electrical output:

h·v>E_{G} [equation (1)],

where h is Plank's constant and v is the wavelength of sunlight.

A solar cell can be mathematically modeled from the electric circuit shown in FIG. 4. Current source I_{cs} is connected in parallel with diode Dₚₙ, which represents the p-n junction. Shunt resistance Rₛₕ represents the internal recombination leakage current inside the cell, and series resistance Rₛ represents the silicon bulk resistance to the output current. Current source I_{cs} represents the maximum current that can be delivered by the solar cell when subject to given solar radiation. The voltage across the diode Dₚₙ is the maximum open circuit voltage, V_{oc}, across the cell.

The output current, I_{cell}, of a solar cell as a function of output voltage, V_{cell}, can be expressed by the following equation:

$${I}_{cell} = [ \begin{matrix}{I}_{sc} - {I}_{0} \cdot [ exp [ \frac{q \cdot ( {V}_{cell} + {I}_{cell} \cdot {R}_{S} )}{k \cdot {T}_{cell}} ] - 1 ] - \\ \frac{{V}_{cell} + {I}_{cell} \cdot {R}_{S}}{{R}_{sh}}\end{matrix} ] , \qquad [ equation ( 2 ) ]$$

where I₀ is the reverse diode (“dark”) current (in amperes); I_{sc} is the maximum (short circuit) current (in amperes) delivered by the solar cell, and is a function of insolation; Rₛₕ and Rₛ are the shunt and series resistance (in ohms) as described above; k is Boltzmann's constant (1.381×10⁻²³ J/K); T_{cell} is the solar cell's temperature (in Kelvin); and q is the charge of an electron (1.6×10⁻¹⁹ C).

The volt-ampere characteristics of an individual solar cell are similar to the volt-ampere characteristics of a plurality of interconnected solar cells that make up a PV module except that the short circuit current, I_{sc}, and open circuit voltage, V_{oc}, are proportionally smaller for a cell than for a module. The open circuit voltage of a cell is equal to E_{G} divided by q, with E_{G} and q as defined above. For a silicon solar cell, the open circuit voltage is equal to 1.11 volts.

As the temperature of the solar cells making up a PV module increases, the quantity of minority carriers increases to effectively reduce the open circuit voltage of the module, and can be determined from the following equation:

$${V}_{oc} = \frac{{E}_{G} ( 0 )}{q} - \frac{kT}{q} \cdot ( \frac{{BT}_{cell}}{{I}_{sc}} ) , \qquad [ equation ( 3 ) ]$$

where

$$[ \frac{{E}_{G} ( 0 )}{q} ]$$

is equal to a cell's open circuit voltage at standard test conditions (25° C.); B is a temperature independent constant reflective of a specific type of cell and method of installation of the plurality of cells in the module; and the remaining terms are as described above.

Typical reduction of the open circuit voltage for a PV module made up of silicon cells is 0.23 mV per degree Celsius. The module's short circuit current increases slightly with increasing temperature. An acceptable industry measure for silicon PV modules and arrays is that for each single degree (Celsius) increase in cell temperature: the open circuit voltage is reduced by 0.37 percent; the short circuit current is increased by 0.05 percent; and the power produced at the MPP drops by 0.5 percent.

FIG. 5 illustrates typical changes in current (amperes) and power (watts) characteristics of a solar cell relative to voltage (volts) subjected to the same level of insolation at different solar cell temperatures. Curves 112(a) and 114(a) represent current and power levels at a relatively lower cell temperature, and curves 112(b) and 114(b) represent current and power levels at a relatively higher cell temperature.

The construction of PV modules 120 typically used for residential PV power generation is illustrated in FIG. 6(a) and FIG. 6(b). The planar configuration of electrically interconnected solar cells 122 is disposed between upper and lower encapsulation layers 124(a) and 124(b). These sealing layers hold the array of interconnected solar cells in position and seal the cells from the external environment. At least the upper sealing layer is typically formed from an optically transparent material. Typically the sealing layers are formed from a low thermal conductivity material, such as a polymer material with a thickness of 100 to 200 microns. One or more separate protective layers 126 provide protection for the module's solar cells from the environment on the front (sun facing) side of the module, and also provide rigidity to the PV module. The protective layer can be of a glass composition having a thickness of about 4 to 5 millimeter, or other suitable material. A backplane 128, formed, for example, from a thin layer of aluminum foil between two thin layers of TEFLON, is typically provided below the lower encapsulation layer to provide protection on the rear (sun opposing) side of the PV module. All layers can be held together with suitable framing material, such as an aluminum frame structure, that is formed into end bracket 130 and 131, and sealant 132.

As shown in FIG. 6(b) ohmic metal-semiconductor contacts 134 are typically made to both the n-type and p-type sides of each solar cell to electrically interconnect the array of cells in the desired series and parallel arrangements with flat wires or metal ribbons. In other cell designs all contacts may be made on one side of the cell. External electrical conductors, such as conductor 136 can be routed out through encapsulation layer 124(b) and backplane 128 for interconnection to another PV module.

The optically transparent encapsulation layers are typically formed from ethylene vinyl acetate (EVA) resin, which has clear optical properties and does not deteriorate over time when exposed to ultraviolet light radiation from sunlight. The EVA resin layer is an excellent electrical insulator and has a relatively high melting point of 90° C. However as true for most polymers, the EVA resin layer has a relatively low thermal conductivity of about 0.16 W/(m·C°).

Alternative non-limiting encapsulation layers may be formed from a transparent colorless fluoropolymer, such as ethylene tetrafluoroethylene (ETFE), with a thermal conductivity of about 0.24 W/(m·C°), or fluorinated ethylene propylene (FEP), with a thermal conductivity of about 0.195 W/(m·C°), on the front side of the array of cells and a polymer suitable for bonding on the opposing side of the cells.

Typically for ground-mounted PV modules, the modules are preferably mounted at a fixed angle based upon the latitude of the installation in an attempt to optimize the total power output from each module, although as mentioned above, solar tracking apparatus is available, if cost justified for a particular installation. This type of module can also be mounted on roofs without supplemental cooling components to cool the solar cells in the module.

In practice an indicator known as the normal operating cell temperature (NOCT) is used to calculate the cell operating temperature and reduction of productivity of PV modules due to temperature. NOCT is defined as the temperature at which the cells in a PV module operate under standard operating conditions, which are: irradiance of 0.8 kW per square meter; 20° C. ambient temperature, and an average wind speed of 1 meter per second, with the module in an open circuit state, the wind oriented parallel to the plane of the module, and all sides of the module fully exposed to the wind. The typical value of NOCT is from 38° C. to 42° C. PV modules are rated at standard insolation of 1 kW per square meter and a cell temperature of 25° C.

PV cell temperature can be calculated from the following equation:

$${T}_{cell} = {T}_{ambient} + \frac{NOCT - 20}{0.8} \cdot S , \qquad [ equation ( 4 ) ]$$

where T_{cell} is the temperature (in Celsius) of the solar cell; T_{ambient} is ambient temperature (in Celsius); S is the insolation (in kW/m²); and NOCT is as described above.

The percentage reduction of performance of a PV array can be calculated from the following equation:

Δ%=0.5%·(T_{cell}−25° C.) [equation (5)],

where Δ% is the relative reduction in generated power from the power generated at 25° C.

Assemblies of PV modules are heated by surrounding ambient air, and by absorption of infrared energy in sunlight that is not converted into electricity. Although the type of PV modules illustrated in FIG. 6(a) and FIG. 6(b) are designed to operate reliably for twenty to thirty years, they do not address cooling of the solar cells making up the module, and therefore, the electrical efficiency of the modules is significantly degraded at elevated ambient temperatures, particularly when a large quantity of modules are connected together to form a solar farm with output power in the range of megawatts.

For PV modules operating in an ambient temperature, T_{ambient}, of 38° C. with insolation of 1 kW per square meter, the temperature of the PV silicon solar cells making up the modules, as calculated from equation (4) above, is about 65.5° C., and the reduction in generated electrical power, as calculated from equation (5) above, is about 20.25 percent of its maximum potential due to the increase in cell temperature.

Typical installations depend solely upon uncontrolled ambient air flow over the outer surfaces of the PV modules, which may be further impeded by the closeness of adjacent modules. The construction of a typical PV module allows dissipation of about a total of 16 watts per meter square per degree Celsius (W/m²·° C.) of thermal energy from the front and back sides of the module surface, with about 7 W/m²·° C. and 9 W/m²·° C. emanating from the front and rear sides, respectively.

Another limitation of present PV modules is that they operate at relatively low voltages. The fabrication of these modules allows multiple modules to be connected electrically in series; however the total series output voltage across the modules is currently limited by safety standards to 600 volts DC in the United States and 1,000 volts DC in Europe.

It is one object of the present invention to improve the efficiency of collecting and converting solar light energy into electric current and power when the solar cells are assembled in a plurality of photovoltaic modules that are interconnected to form a photovoltaic collector by providing an efficient thermal operating environment for the solar cells in the photovoltaic modules making up the collector.

It is another object of the present invention to increase the effective DC voltage at the output of each photovoltaic collector, which is of benefit in applications for high power generation, for example, in solar farms having output capacities greater than one megawatt.

### SUMMARY OF THE INVENTION

In one aspect the present invention is an air-cooled, high-heat dissipation, photovoltaic module, and method of forming such a photovoltaic module.

In another aspect the present invention is an air-cooled, high heat dissipation, photovoltaic collector assembled from a plurality of interconnected photovoltaic modules, and method of forming such a photovoltaic collector.

In another aspect the present invention is an air-cooled, high-heat dissipation, photovoltaic high voltage collector assembled from a plurality of interconnected photovoltaic modules, and method of forming such a photovoltaic high voltage collector. The photovoltaic high voltage collector can be optionally mounted on a solar tracker to maximize collection of solar power. A plurality of photovoltaic high voltage collectors, with or without solar trackers, can be assembled into a solar farm for generation of multi-megawatt levels of AC power when the plurality of photovoltaic high voltage collectors are connected to a suitable arrangement of DC to AC inverter apparatus.

In another aspect the present invention is a photovoltaic power collector and method of making a photovoltaic power collector. The photovoltaic power collector comprises a plurality of air cooled photovoltaic modules that are electrically interconnected to form a photovoltaic power source having a photovoltaic power collector output capable of maintaining a peak DC voltage of at least 1,000 volts. Each air cooled photovoltaic module comprises a number of solar cells electrically connected in series that can be mounted on a linearly oriented substrate with the solar cells physically arranged in a single row on a first side of the linearly oriented substrate. The linearly oriented substrate is formed from a thermally conductive composition and has an expanded heat dissipation-to-ambient surface region on a second side of the linearly oriented substrate that is opposite the first side of the substrate. Multiple air cooled photovoltaic modules can be interlocked together to form the photovoltaic power collector. The photovoltaic power collector can be electrically isolated from electrical ground potential and each of the interconnected air cooled photovoltaic modules can be electrically isolated from all other of the air cooled photovoltaic modules. The photovoltaic power collector can include a separate step-up voltage regulator, or step-down current regulator, that is connected to the output of the collector.

In another aspect the present invention is a photovoltaic power collection circuit and method of forming a photovoltaic power collection circuit. The photovoltaic power collection circuit has an output capable of maintaining a peak DC power level of at least one megawatt and comprises a plurality of photovoltaic power collectors. Each photovoltaic power collector can comprise a plurality of air cooled photovoltaic modules as described above. The plurality of air cooled photovoltaic modules are electrically interconnected to form a collector photovoltaic power source having an output capable of maintaining a peak DC voltage of at least 1,000 volts. The photovoltaic power collection circuit may also comprise a separate step-up voltage regulator having its input exclusively connected to the output of one of the photovoltaic power collectors with the outputs of all of the separate step-up voltage regulators connected together in parallel to form the photovoltaic power collection circuit output. The separate step-up voltage regulator maintains the output of its associated photovoltaic power collector at the maximum power point for the plurality of solar cells making up the associated photovoltaic power collector. The photovoltaic power collection circuit may also comprise a separate step-down current regulator having its input exclusively connected to the output of one of the photovoltaic power collectors with the outputs of all of the separate step-down current regulators connected in series to form the photovoltaic power collection circuit output. The separate step-down current regulator maintains the output of its associated photovoltaic power collector at the maximum power point for the plurality of solar cells making up the associated photovoltaic power collector.

The above and other aspects of the invention are further set forth in this specification and appended claims.

### BRIEF DESCRIPTION OF THE DRAWINGS

The appended drawings, as briefly summarized below, are provided for exemplary understanding of the invention, and do not limit the invention as further set forth in this specification and the appended claims:

FIG. 1 is a partial diagram of a typical photovoltaic array formed from a plurality of interconnected photovoltaic modules.

FIG. 2 is a simplified electrical diagram of a typical photovoltaic module.

FIG. 3 graphically illustrates the electrical performance characteristics of a typical photovoltaic module.

FIG. 4 is an electric circuit used to mathematically model a solar cell.

FIG. 5 graphically illustrates the electrical performance characteristics of a typical solar cell.

FIG. 6(a) and FIG. 6(b) illustrate in exploded and partial cross sectional views, respectively, one type of construction of a photovoltaic module.

FIG. 7(a) illustrates in an exploded partial isometric view one example of a linear encapsulated solar cell assembly and cover material used in a photovoltaic module of the present invention.

FIG. 7(b) illustrates in a partial isometric view one example of a linear mounting structure used with a photovoltaic module of the present invention.

FIG. 7(c) illustrates in cross sectional view an interlocking arrangement of the linear mounting structure shown in FIG. 7(b).

FIG. 7(d) illustrates in cross sectional view one example of a photovoltaic module of the present invention.

FIG. 7(e) illustrates in partial isometric view one example of a photovoltaic module of the present invention.

FIG. 8(a) and FIG. 8(b) illustrate one method of forming a photovoltaic module of the present invention.

FIG. 9(a) is a planar view of one example of a framed photovoltaic collector of the present invention suitable for use in low voltage applications.

FIG. 9(b) is a planar view of one example of a framed photovoltaic collector of the present invention suitable for use in high voltage applications.

FIG. 9(c) is a partial planar view of the framed photovoltaic collector in FIG. 9(b) that shows electrical insulators between photovoltaic modules and the frame of the collector.

FIG. 9(d) is a cross sectional detail of one example of providing electrical isolation between adjacent interlocking photovoltaic modules in a photovoltaic collector of the present invention suitable for use in high voltage applications.

FIG. 10(a) is a simplified schematic of the electrical connections between the photovoltaic cells forming a photovoltaic collector of present invention.

FIG. 10(b) is a simplified schematic of electrical series interconnection between the photovoltaic modules forming a photovoltaic collector of present invention.

FIG. 10(c) is a simplified diagrammatic representation of three photovoltaic power collectors of the present invention electrically connected in parallel to form a photovoltaic power collection circuit.

FIG. 10(d) illustrates a unified framing arrangement for the three photovoltaic power collectors shown in FIG. 10(c).

FIG. 10(e) is a simplified electrical schematic representation of the three photovoltaic power collectors shown in FIG. 10(c).

FIG. 11 is a simplified electrical schematic representation of three photovoltaic power collectors of the present invention electrically connected in parallel via step-up voltage regulators to form a photovoltaic power collection circuit.

FIG. 12 is a simplified schematic representation of three photovoltaic power collectors of the present invention electrically connected in series via step-down current regulators to form a current collection circuit.

FIG. 13 is a schematic diagram for one example of a step-up voltage regulator used in some examples of the present invention.

FIG. 14 is a schematic diagram for one example of an electrical isolation step-down current regulator used in some examples of the present invention.

FIG. 15 is a series of graphs related to the operation of the electrical isolation step-down current regulator shown in FIG. 14.

FIG. 16 is a series of graphs related to the operation of the step-up voltage regulator shown in FIG. 13.

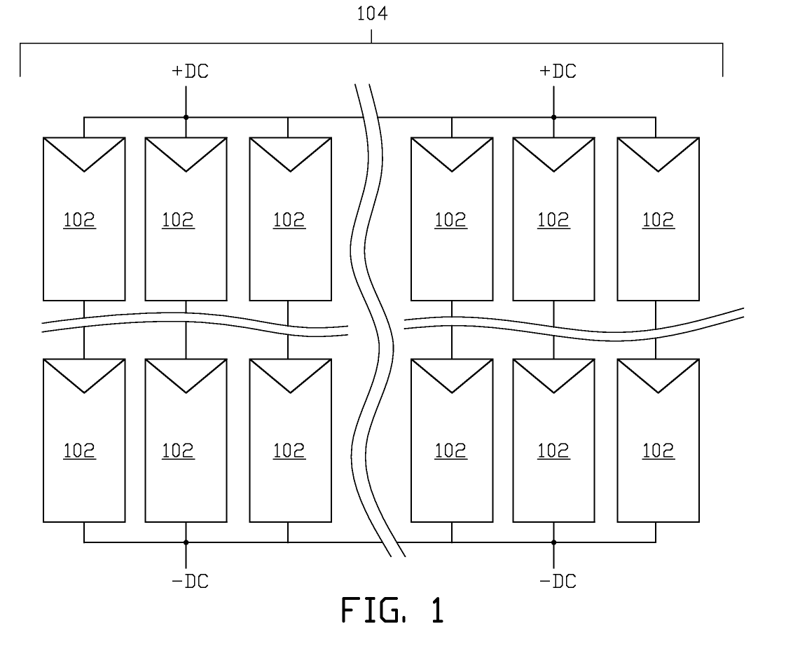

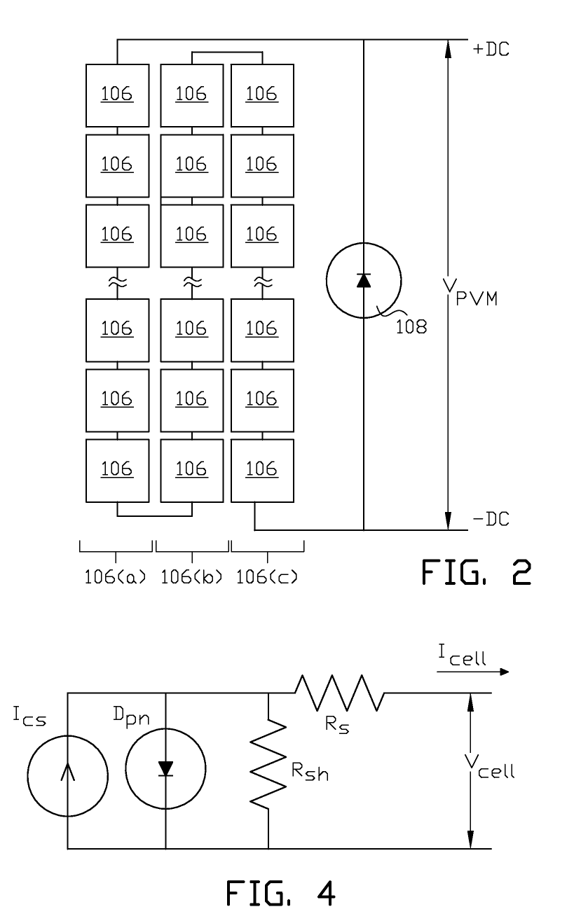

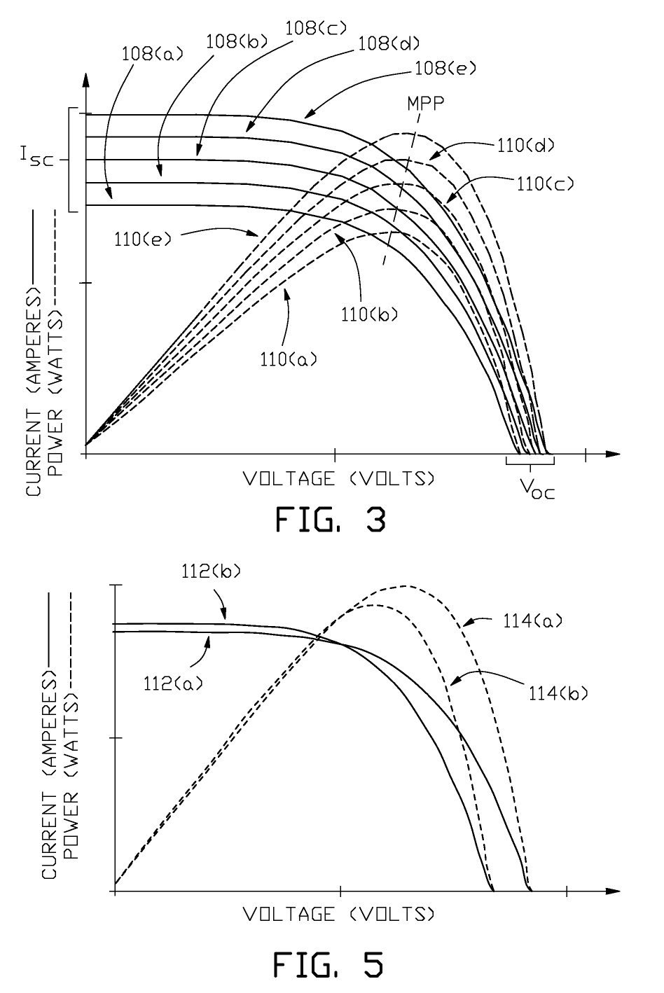

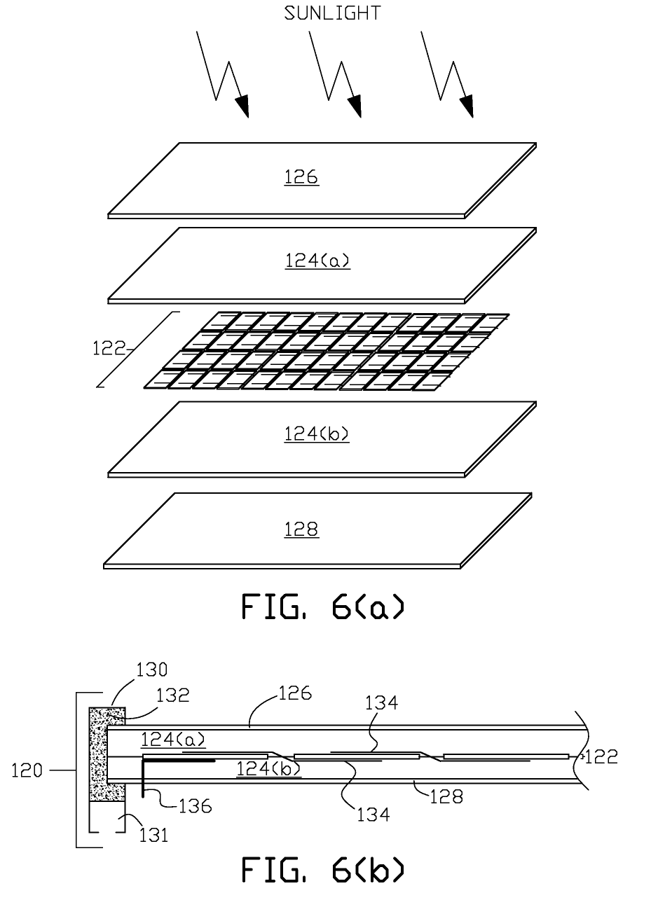

### DETAILED DESCRIPTION OF THE INVENTION

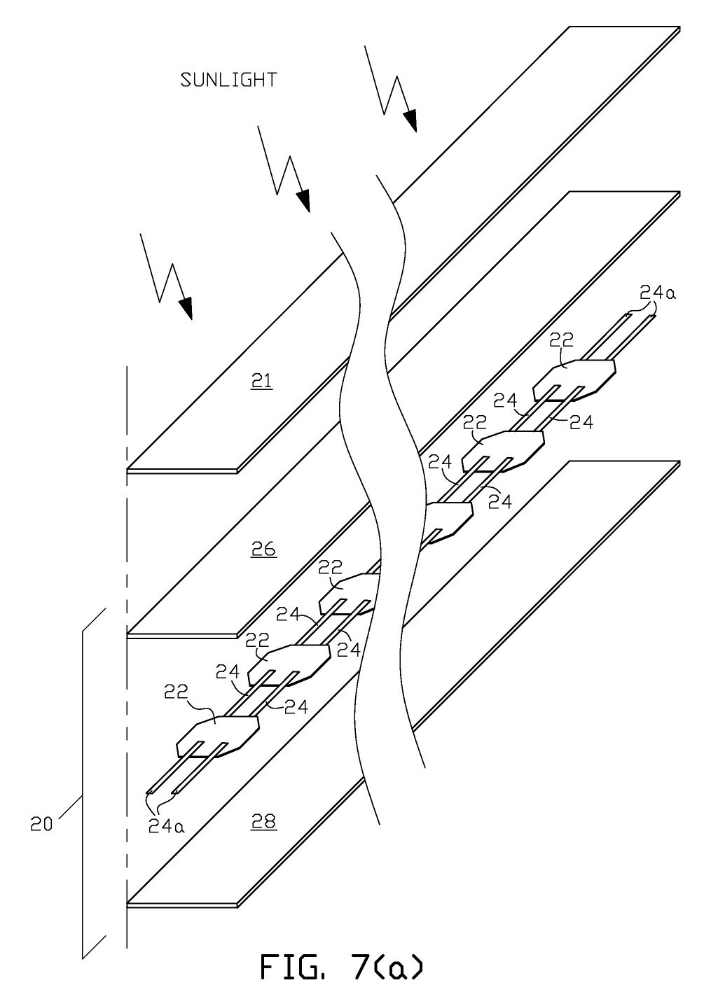

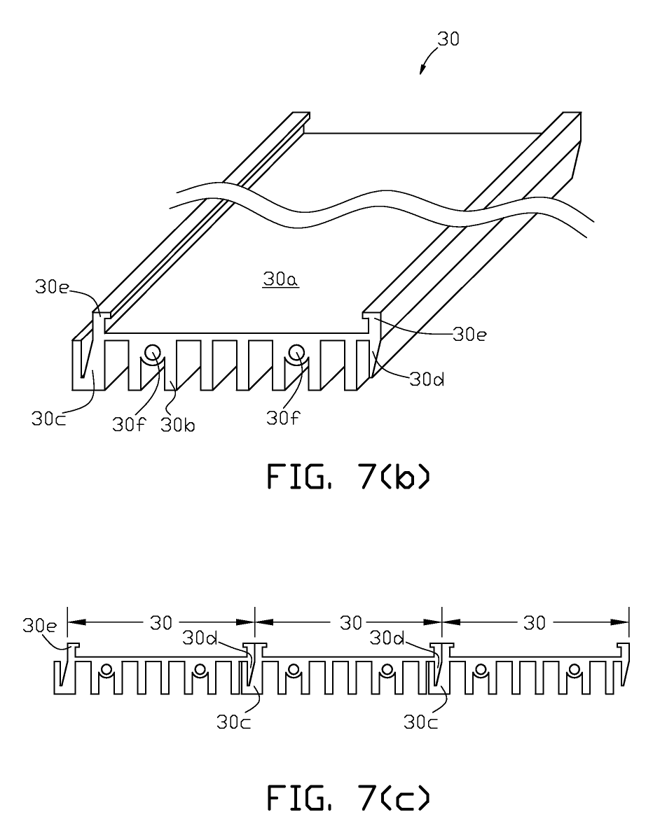

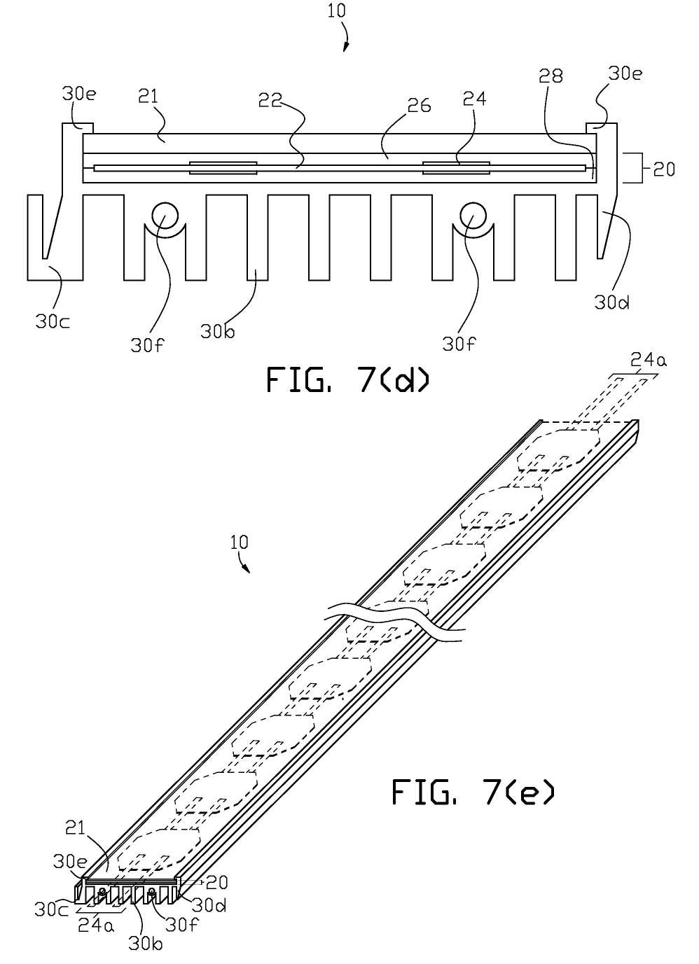

There is shown in FIG. 7(a) through FIG. 7(e) one example of a PV module 10 of the present invention. PV module 10 comprises linear encapsulated solar cell assembly 20 and thermally conductive linear mounting structure 30.

As best seen in FIG. 7(a) linear encapsulated solar cell assembly 20 comprises a row of solar cells 22 electrically interconnected in series by suitable electrical conducting elements 24. In one particular non-limiting example of the invention further described below, there are a total of thirty solar cells connected in series in linear encapsulated solar cell assembly 20. The row of electrically interconnected solar cells is encapsulated between upper and lower encapsulation layers 26 and 28 respectively. The solar cells may be of any type, as suitable for a particular application. The upper and lower encapsulation layers serve primarily as protection of the solar cells, for example, from breakage. The upper and lower encapsulation layers can be formed from any suitable ultraviolet stabilized thin (for example, between 300 to 400 microns) film material, such as an ethylene vinyl acetate (EVA) resin. Cover material 21, as further described below, can be placed over the linear encapsulated solar cell assembly for further protection of the solar cell assembly once the solar cell assembly is placed in linear mounting structure 30.

One example of the linear mounting structure 30 of the present invention, which is a thermally efficient linearly oriented substrate, is shown in FIG. 7(b). Linear encapsulated solar cell assembly 20 and cover material 21 (if used) are located on top surface 30a of mounting structure 30 as illustrated in FIG. 7(d) and FIG. 7(e) to form PV module 10. Expanded surface elements 30b, shown in this non-limiting example as spaced apart fins, extend from the rear of mounting structure 30 to enhance heat transfer to ambient. Linear mounting structure 30 is formed from a composition having a relatively high value of thermal conductivity, that is, greater than about 200 W/m·° C. Aluminum or copper compositions are examples of suitable materials for the mounting structure. Longitudinal interlocking elements 30c and 30d can optionally be provided to facilitate interconnection, either structurally, or structurally and electrically, of multiple PV modules as further described below. In some examples of the invention, the relatively long and narrow configuration of a PV module favors fabrication of the linear mounting structure via an extrusion process. Some or all of the retaining elements 30e for the encapsulated solar cell assembly 20 and cover material 21 (if used) can be integrated into the extruded mounting structure. Similar mounting elements 30f can also be integrated into the extruded mounting structure.

Since linear mounting structure 30 provides a rigid substrate for encapsulated solar cell assembly 20, a relatively thick and rigid cover material, such as 4 to 5 mm thick glass, is not necessarily required. Alternatively, if required at all, a thin sheet of TEFLON, or other thin film that is flexible, transparent and ultraviolet resistant, can be used for cover material 21. One advantage of thin film cover material is that thermal dissipation from the front of the PV module can be increased from 7 W/m²·° C. to about 10 W/m²·° C.

The expanded surface elements 30b of mounting structure 30 increase thermal dissipation from the rear of the PV module from about 9 W/m² ° C. to about 40 W/m² ° C., which is a better than threefold improvement in heat dissipation over the previously described prior art. At an ambient temperature of 38° C. and insolation of 1 kW per square meter, the temperature of a solar cell will be reduced from 65.5° C. to 46° C. The reduction of the electrical output of a solar cell will only be 10.5 percent, as compared with the prior art 20.25 percent reduction, which is better than a 48 percent improvement.

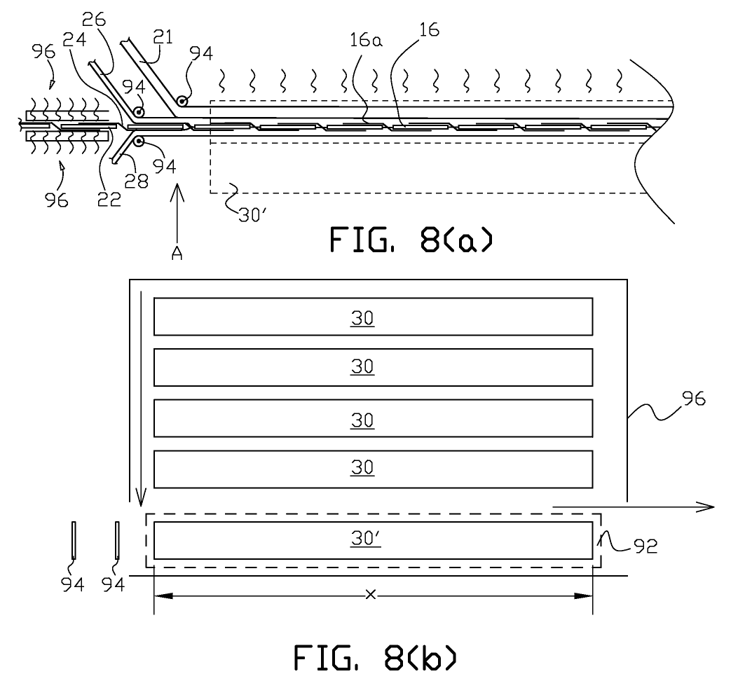

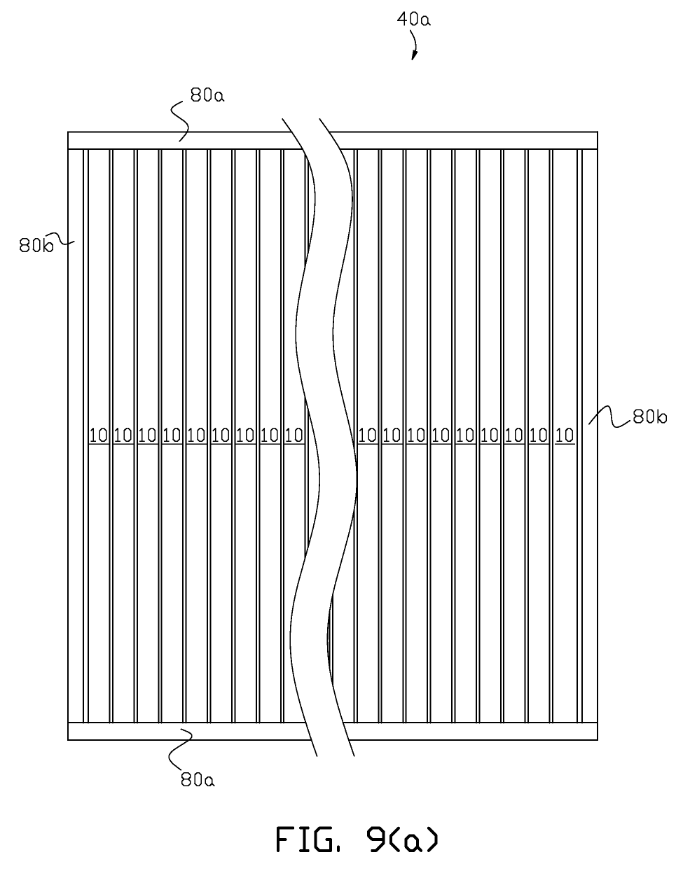

FIG. 8(a) and FIG. 8(b) illustrate one example of a method of fabricating a PV module 10 used in the present invention. Referring to FIG. 8(b) one or more linear mounting assemblies 30 are preheated by means of a suitable heating apparatus 96 that may be, for example, an oven. One mounting structure 30′ is brought into position in the linear encapsulated solar cell assembly and cover material mating area 92 in a suitable fashion so that solar cell assembly 20 and cover material 21 can positioned over the top surface 30a (FIG. 7(b)) of linear mounting structure 30′.

Lower encapsulation layer sheet material 28, solar cells 22, interconnecting cell electrical leads 24, upper encapsulation layer sheet material 26, and cover sheet material 21 are laminated (sandwiched) together at point A (FIG. 8(a)) to form linear encapsulated solar cell assembly 20, with the overlaid cover material, if used. Lower and upper encapsulation materials and the cover material can be fed from suitable rolled sources (not shown in the figures) of each material via tensioning rollers 94 and other feeding apparatus not shown in the figures.

While examples of the invention generally describe a PV module with a cover material, upper and lower encapsulation layers in which the series array of solar cells are embedded and arranged on a linear mounting structure, other examples of the invention may include more or less layers, including, by way of example and not limitation, one or more light concentrator layers that can be formed, for example, as lenses for concentrating light on the solar cells. In its broadest aspect the present invention can be applied to any PV module wherein the array of solar cells making up the linear arrangement is “sealed” between two encapsulation layers, and where the term “sealed” means at least protecting the solar cells from mechanical damage and moisture when the entire PV module is assembled.

Solar cells 22 and interconnecting electrical leads 24 are sequentially fed between the lower and upper encapsulation materials before they are sandwiched together. Bonding sources 96 bond the electrical leads to adjacent solar cells to form the series electrical connections in the PV module. The bonding source may be of any suitable type, for example, mass heating sources such as resistance heaters, or molecular heating sources, such as ultrasonic welders. Not shown in FIG. 8(a) and FIG. 8(b) are the external end electrical connections 24a (FIG. 7(a)), which can be bonded to the end solar cell at each opposing end of an assembled PV module.

Mechanical apparatus (not shown in the figures) can be provided to appropriately move and position mounting structure 30′ relative to process laminating station A. An array lamination cutting device can be used to cut the encapsulated solar cell assembly and cover material when the entire length of the front surface of the mounting structure is covered with the solar cell assembly and cover material. Additional heating, application of a pressure force, or application of a vacuum may also be used to assist bonding the encapsulated solar cell assembly and cover material together, and/or bonding the encapsulated solar cell assembly to the front surface of mounting structure 30′.

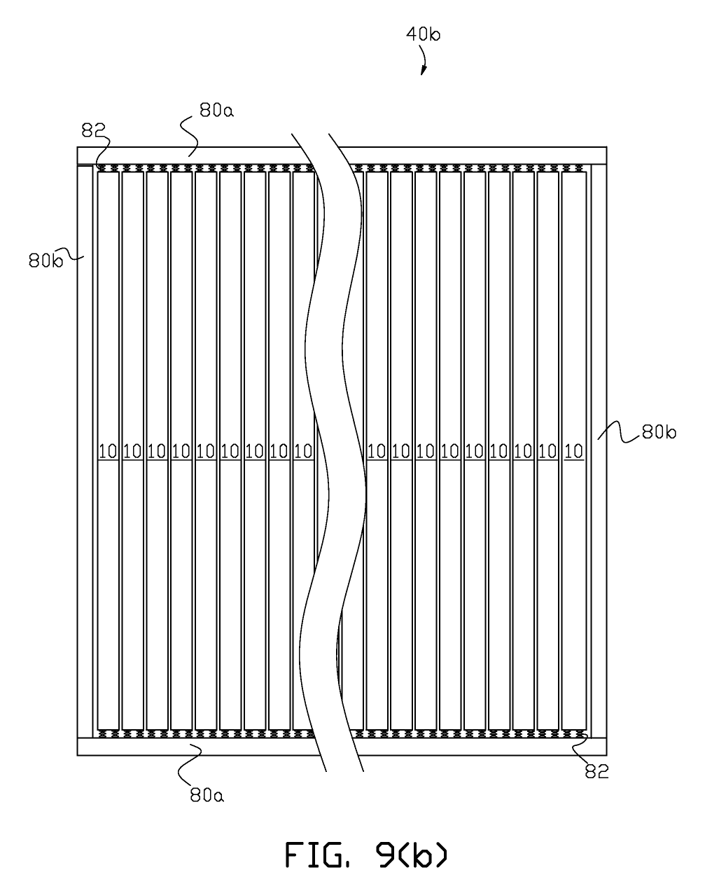

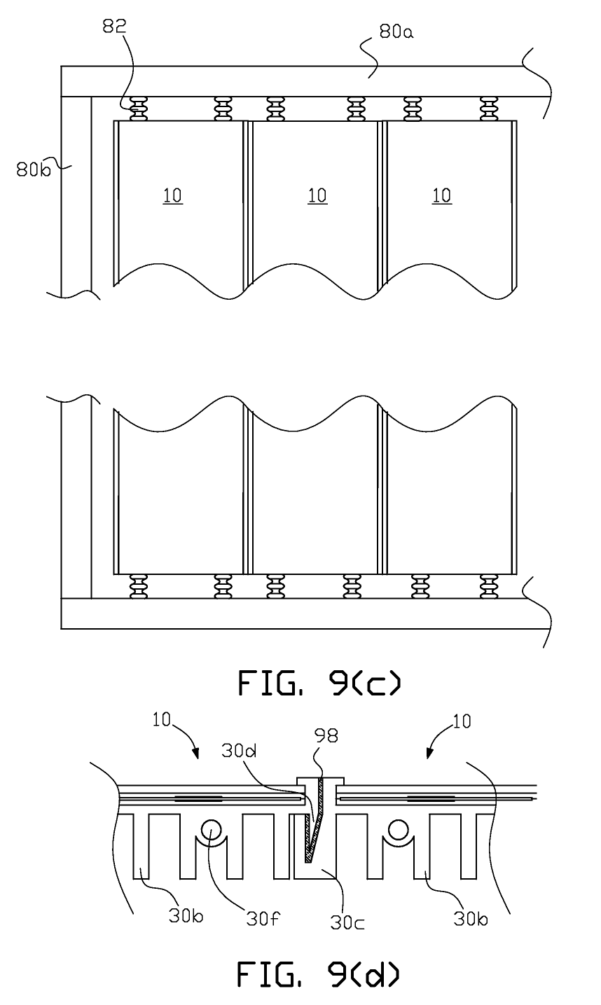

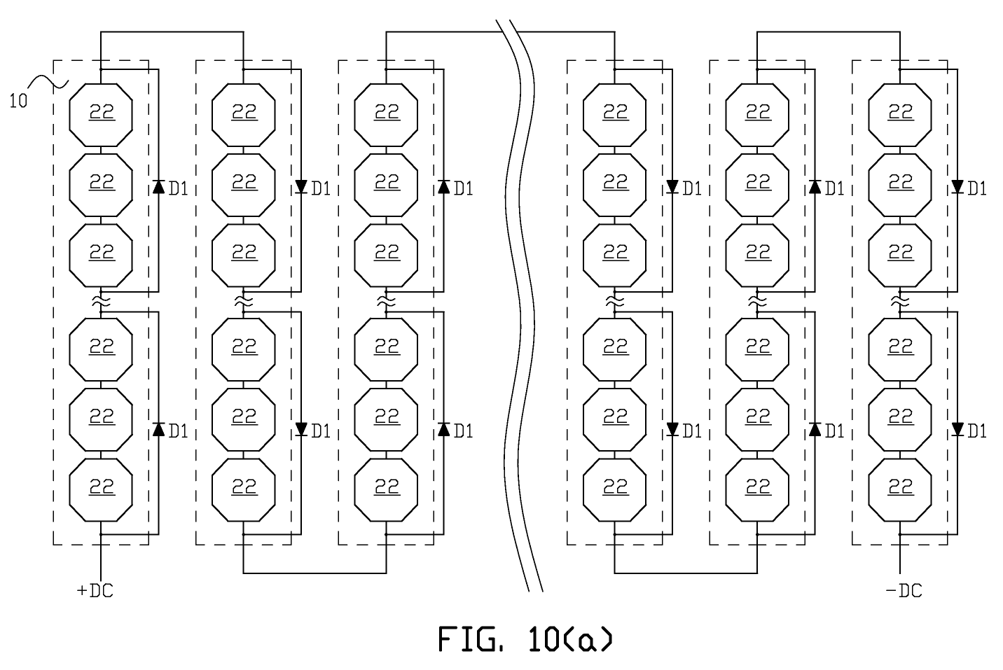

Multiple PV modules 10 can be connected together, both structurally and electrically, to form a suitable PV collector, such as for example, the collectors illustrated in FIG. 9(a) or FIG. 9(b). PV collector 40a in FIG. 9(a) is illustrated without electrical isolation from its frame as typically used in low voltage (1,000 volts or less) applications; PV collector 40b in FIG. 9(b) is illustrated with electrical isolation from its frame as typically used in high voltage (greater than 1,000 volts) applications. Suitable framing elements 80a and 80b are used to frame the multiple PV modules making up the PV collector.

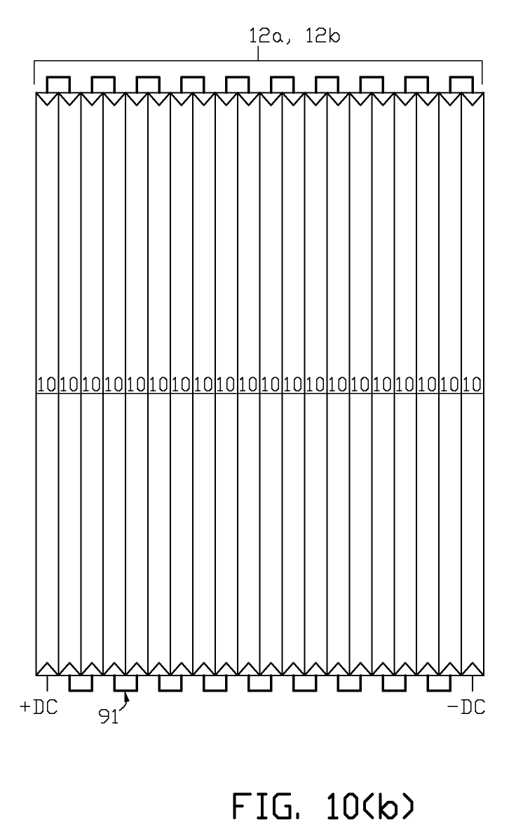

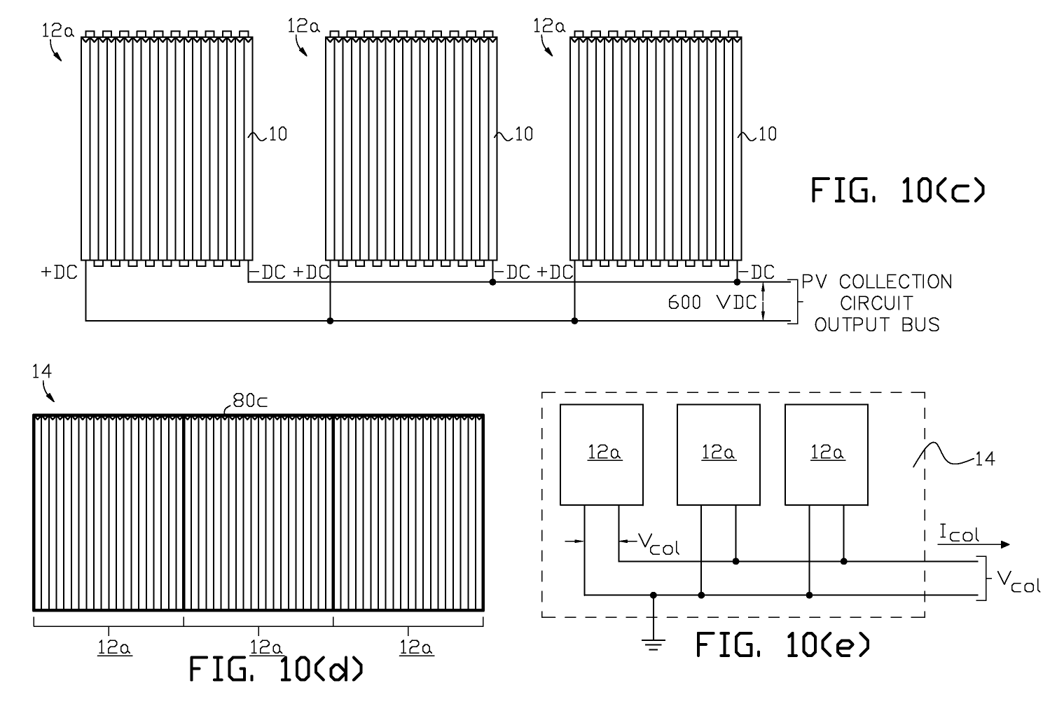

For high voltage applications suitable electrical insulating elements (82 in FIG. 9(b)) can be used to isolate the multiple PV modules making up the PV collector from its frame and to provide a sufficient dielectric barrier (material 98 in FIG. 9(d)) between each of the PV modules. In some examples of the invention, end mounting elements 30f (FIG. 7(b)) may be utilized to fasten insulators 82 to the ends of the PV modules. Referring to FIG. 9(d) suitable electrical isolation can be provided between adjacent interlocking PV modules that make up a high voltage collector. In this example suitable electrical insulating material 98, formed for example, from a KEVLAR composition, is provided between the interlocking elements 30c and 30d of adjacent PV modules. FIG. 10(a) illustrates schematically the electrical connections between series connected multiple PV solar cells 22 (with typical protective bypass diodes D1) that make up each PV module 10. Connections at the end of each PV module and mounting of the diodes can be accomplished in any suitable physical arrangement. With one non-limiting arrangement of sixty series connected solar cells in each PV module, and sixty PV modules making up the high voltage PV collector, a peak DC voltage of from approximately 1.9 kV to 2.2 kV can be achieved across output terminals +DC and −DC of the high voltage PV collector.

A framed high voltage PV collector 40b comprising at least thirty PV modules with each PV module comprising at least thirty solar cells will have an overall surface area of approximately 25 meters square, and be of such weight that the high voltage PV collector could be mounted on a solar tracker utilizing, for example, active single or dual axis tracking. Depending upon the particular application the PV collector may have more than thirty PV modules and/or each PV module may have more than thirty solar cells.

FIG. 10(b) illustrates one example of the physical arrangement of PV collector 12a or 12b of the present invention where the group of PV modules 10 making up the collector have their DC outputs connected in series as diagrammatically illustrated by typical electrical connecting element 91.

FIG. 10(c) illustrates one example of the physical arrangement of three low voltage PV collectors 12a having their DC outputs connected together in parallel to form a PV power collector circuit 14 as illustrated in FIG. 10(e), for example, with a nominal circuit low voltage output of 600 volts DC. As shown in FIG. 10(d) the three low voltage PV collectors may be framed within a common frame structure 80c. While three collectors are illustrated in FIG. 10(c) a different number of collectors may be utilized in other examples of the invention.

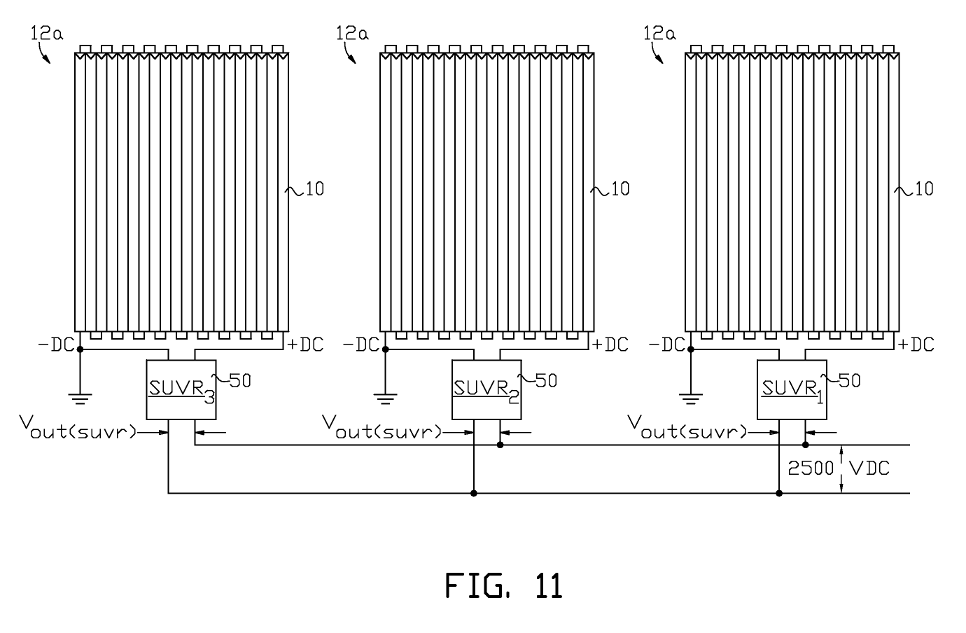

FIG. 11 illustrates one arrangement of the present invention that is particularly suitable for high voltage applications. Each PV collector 12a comprises an array of solar photovoltaic modules 10 electrically connected in series. The DC output of each collector 12a is connected to the input of a separate collector step-up voltage regulator SURV. Consequently the DC output voltage, Vₒᵤₜ₍ₛᵤᵥᵣ₎, of each solar power collector 12a (at the output of the step-up voltage regulator), can be held at a relatively constant and high voltage value of, for example, 2,500 volts, while the DC output current (Iₒᵤₜ₍ₛᵤᵥᵣ₎) of each solar PV power collector 12a varies in accordance with the instantaneous MPP for each individual solar PV power collector shown in FIG. 11. As noted above, the MPP is defined as the point at which the solar cell can deliver maximum electrical power (maximum voltage multiplied by current) for a given insolation level and electrical load applied to the collector. Without output voltage equalization for each PV module making up a solar power collection circuit, the instantaneous DC output voltage, V_{col}, of a collector 12a may vary over a range (for example, between 400 and 600 volts) depending upon the instantaneous incident level of illumination (insolation) on the solar cells utilized in the PV collectors. The term “photovoltaic module” is used herein in the broadest sense to define one or more solar cells contained in any type of enclosure such as, but not limited to, what is commonly known as a photovoltaic module. While three collectors are illustrated in FIG. 11 (with an associated SUVR) a different number of collectors may be utilized in other examples of the invention.

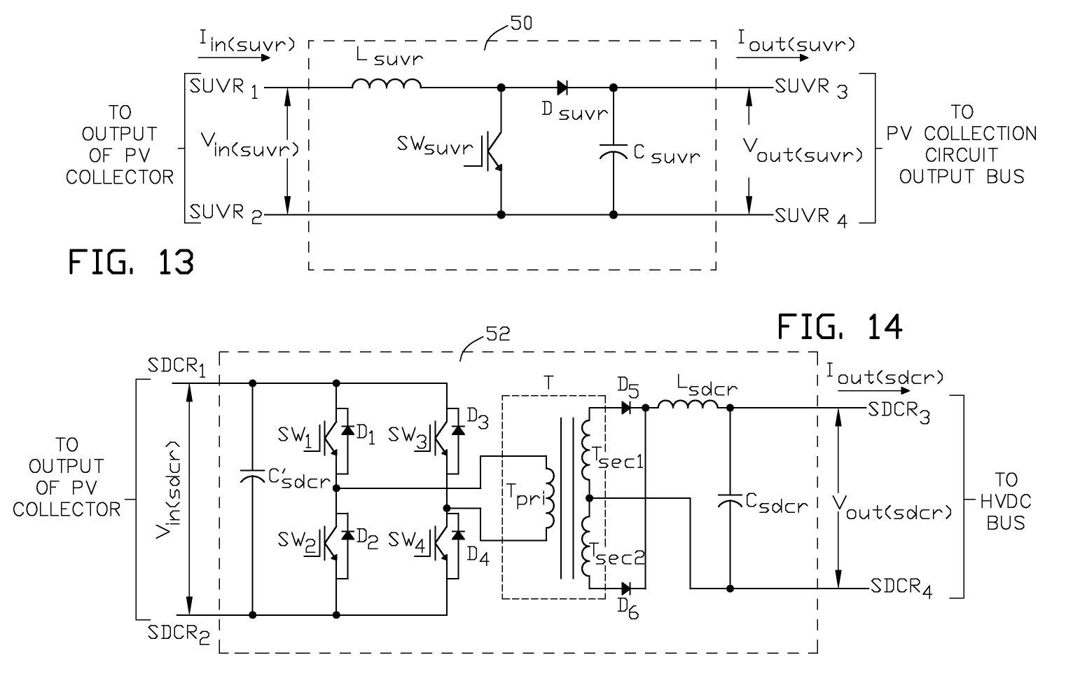

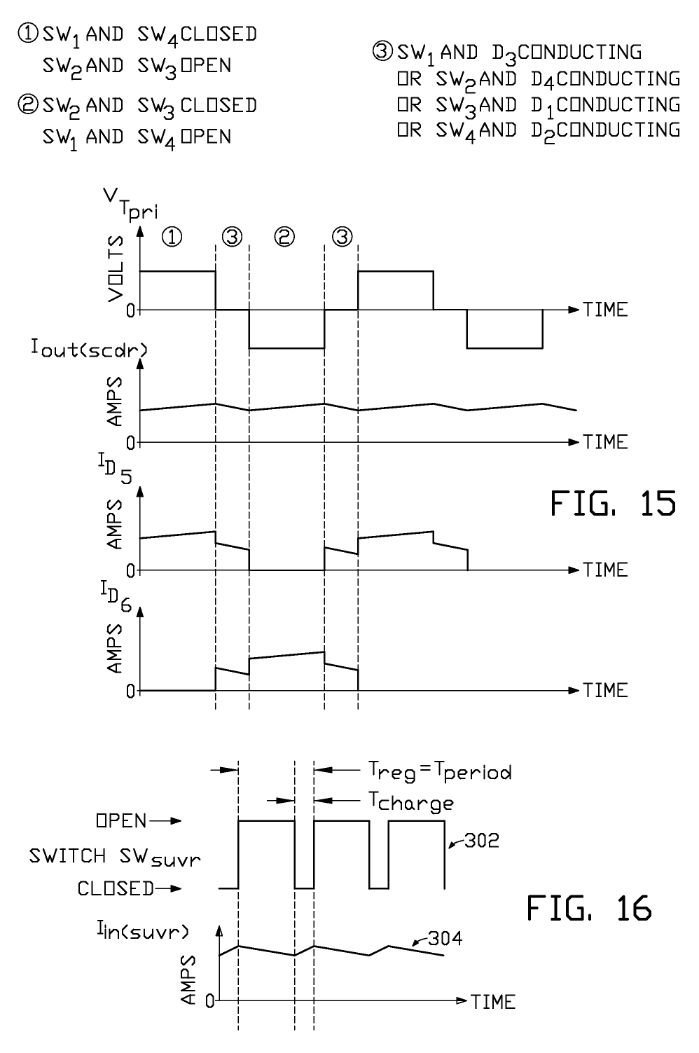

One typical, but non-limiting scheme for implementing step-up voltage regulation in each PV collector is the step-up voltage regulator (SUVR) 50 shown in FIG. 13. Input terminals SUVR₁ and SUVR₂ are connected across the output of the series electrically-connected array of PV modules 10 making up PV collector 12a. Switching device SWₛᵤᵥᵣ periodically connects inductive energy storage device Lₛᵤᵥᵣ across the output of the series connected array of PV modules. Energy storage device Lₛᵤᵥᵣ (such as an inductor) stores energy that is transferred to capacitive energy storage device Cₛᵤᵥᵣ (such as a capacitor) via diode Dₛᵤᵥᵣ. The relationship between the output voltage, Vₒᵤₜ₍ₛᵤᵥᵣ₎, and input voltage, Vᵢₙ₍ₛᵤᵥᵣ₎, of the SUVR is defined by the following equation:

$${V}_{out ( suvr )} = \frac{1}{Δ} \cdot {V}_{i n ( suvr )} , \qquad [ equation ( 6 ) ]$$

where Δ is defined as the duty cycle of the SUVR in the following equation:

$$Δ = \frac{{T}_{period} - {T}_{charge}}{{T}_{period}} , \qquad [ equation ( 7 ) ]$$

where T_{charge} is equal to the period of time for storing energy in the inductive energy storage device Lₛᵤᵥᵣ, and T_{period} is equal to the time period of repetition of the charging cycles. The relationship between output current, Iₒᵤₜ₍ₛᵤᵥᵣ₎, and input current, Iᵢₙ₍ₛᵤᵥᵣ₎, of the step-up voltage regulator is defined by the following equation:

Iₒᵤₜ₍ₛᵤᵥᵣ₎=Iᵢₙ₍ₛᵤᵥᵣ₎·Δ [equation (8)],

and the relationship between output power, Pₒᵤₜ₍ₛᵤᵥᵣ₎, and input power, Pᵢₙ₍ₛᵤᵥᵣ₎, of the step-up voltage regulator can be defined by the following equations:

Pₒᵤₜ₍ₛᵤᵥᵣ₎=(Iₒᵤₜ₍ₛᵤᵥᵣ₎·Vₒᵤₜ₍ₛᵤᵥᵣ₎)=Pᵢₙ₍ₛᵤᵥᵣ₎=(Iᵢₙ₍ₛᵤᵥᵣ₎·Vᵢₙ₍ₛᵤᵥᵣ₎) [equation (9)]

The waveforms in FIG. 16 illustrate various features of the SUVR simplified schematic shown in FIG. 13. In one exemplary regulation scheme, each regulation time period (T_{reg}) illustrated in FIG. 16, is a multiple of one-sixth of the line voltage time period of the AC electric power transmission network (grid) to which the output power of the SUVR is ultimately connected after appropriate conversion to AC power via a suitable arrangement of DC to AC inverter apparatus, for example, as illustrated in U.S. patent application Ser. No. 12/032,910, which is hereby incorporated by reference in its entirety, to minimize the ripple effect on the output three phase grid synchronized currents of the inverter apparatus; that is, the regulation time period can be ⅙^{th}, 1/12^{th}, 18^{th} . . . of the grid's line voltage time period, which is 167 milliseconds for a nominal 60 Hertz grid, or 200 millisecond for a nominal 50 Hertz grid. During each regulation period (T_{reg}) switch SWₛᵤᵥᵣ is closed for a “charge” time period (T_{charge}), and open for the remainder of the regulation period as illustrated by waveform 302 in FIG. 16. When switch SWₛᵤᵥᵣ is closed, inductor Lₛᵤᵥᵣ stores energy supplied by an increasing DC current as illustrated by the regions of waveform 304 with a positive slope. When switch Sₛᵤᵥᵣ is open, stored energy in inductor Lₛᵤᵥᵣ flows to capacitor Cₛᵤᵥᵣ, as illustrated by the regions of waveform 304 with a negative slope, to store charge energy in the capacitor. This arrangement allows inductor Lₛᵤᵥᵣ to charge capacitor Cₛᵤᵥᵣ to a voltage level greater than the instantaneous SUVR input DC voltage level, and allows continuous operation of the SUVR, as defined by the instantaneous MPP for the particular output regulated PV collector, when the instantaneous SUVR input DC voltage level, Vᵢₙ₍ₛᵤᵥᵣ₎, is below the operating DC voltage input to the inverter apparatus as required to inject AC current onto the grid.

The SUVR circuit shown in FIG. 13 is one non-limiting example of a circuit that can be used as a SUVR in the present invention to perform the function of a step-up voltage regulator as described above.

Therefore step-up voltage regulator 50 converts an unstable DC voltage source comprising an array of PV modules 10 making up PV collector 12a into a stable DC voltage source operating at the MPP. The duty cycle of a SUVR can periodically be adjusted in each regulation period for each PV collector to achieve maximum Pₒᵤₜ₍ₛᵤᵥᵣ₎, which is equal to the sum of the power levels at the MPP of all the PV collectors.

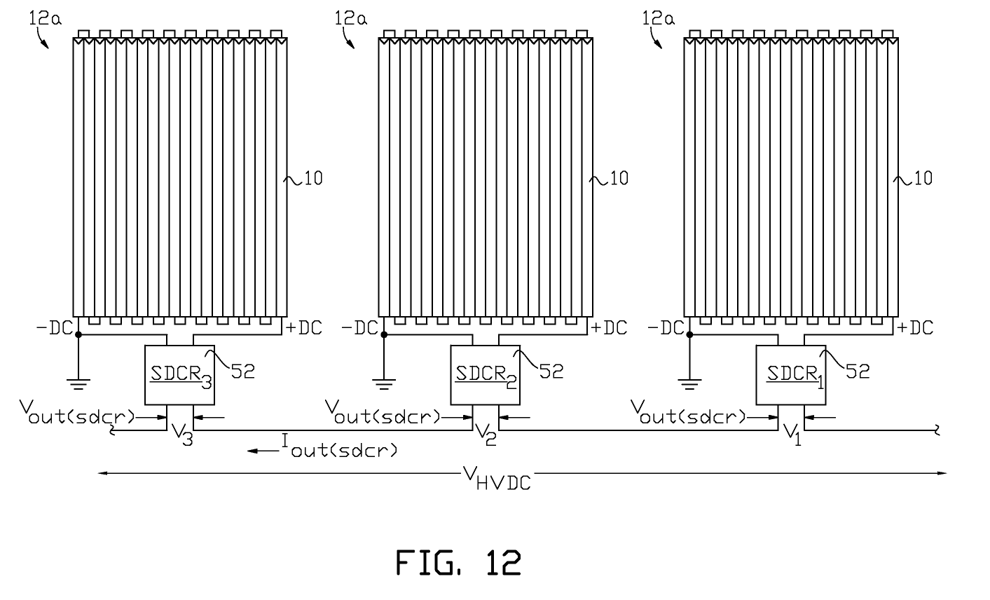

FIG. 12 illustrates another arrangement of the present invention. Each PV collector 12a comprises an array of solar photovoltaic modules 10 electrically connected in series. As shown in FIG. 12 the DC output of each collector 12a is connected to the input of a separate PV collector-isolated step-down current regulator SDCR. The outputs of all step-down current regulators 52 are electrically interconnected in series to provide a DC voltage level, V_{HVDC}, that is greater than that of the output of a single SDCR, and can be fed to DC to AC power conversion equipment (inverter apparatus) via a high voltage DC (HVDC) transmission link at voltage (V_{HVDC}) levels typically as high as 50 to 500 kilovolts. The output of each step-down current regulator 52 is electrically isolated from its input to allow each PV collector to be connected (referenced) to electrical ground potential while the output of each step-down current regulator in the serially connected circuit is voltage-referenced to the summed output voltages of all preceding current regulators in the series. That is, for example, in FIG. 12, the output voltage V₃ of SDCR₃ is summed to the output voltage values V₁ and V₂ of SDCR₁ and SDCR₂, respectively. Since the outputs of all step-down current regulators are connected in series, the resulting common string circuit current for the output of all the regulators will be equal. While three collectors (with associated SDCR) are illustrated in FIG. 11 a different number of collectors may be utilized in other examples of the invention.

One typical, non-limiting scheme for implementing step-down current regulation in the PV collector-isolated step-down current regulator 52 is illustrated in FIG. 14. The waveforms in FIG. 16 illustrate various features of the SDCR shown in FIG. 14. The regulation period for an SDCR is preferably selected in a fashion similar to that for a SUVR as described above. The transformer's primary voltage, V_{Tpri}, is positive when switching devices S_{W1} and S_{W4} are conducting and is negative when switching devices S_{W2} and S_{W3} are conducting. The transformer voltage V_{Tpri} is zero when one of the following diode-switch pair is conducting: D₁ and SW₃; D₂ and SW₄; D₃ and SW₁; or D₄ and SW₂. When voltage V_{Tpri} is positive, energy is stored in inductor L_{sdcr} via diode D₅, and when voltage V_{Tpri} is negative, energy is stored in inductor L_{sdcr} via diode D₆; the gradient of current I_{out(sdcr)} in both of these cases is positive. When the transformer voltage, V_{Tpri}, is zero, energy is discharged into the load and current flows through both diodes D₅ and D₆. The gradient of current I_{out(sdcr)} in this case is negative.

The SDCR circuit shown in FIG. 14 is one non-limiting example of a circuit that can be used as a SDCR to perform the function of a step-down current regulator as described above.

The DC output current I_{out(sdcr)} as shown in FIG. 14 of each PV collector-isolated step-down current regulator 52 is held relatively constant in magnitude and is equal to the common string current, while the DC output voltage V_{out(sdcr)} varies in accordance with the power input to the step-down current regulator. All step-down current regulators 52 have their outputs connected together in series as shown in FIG. 12, and supply HVDC power to the high voltage DC transmission link.

The above examples of the invention have been provided merely for the purpose of explanation, and are in no way to be construed as limiting of the present invention. While the invention has been described with reference to various embodiments, the words used herein are words of description and illustration, rather than words of limitations. Although the invention has been described herein with reference to particular means, materials and embodiments, the invention is not intended to be limited to the particulars disclosed herein; rather, the invention extends to all functionally equivalent structures, methods and uses, such as are within the scope of the appended claims. Those skilled in the art, having the benefit of the teachings of this specification, may effect numerous modifications thereto, and changes may be made without departing from the scope of the invention in its aspects.

1. A solar photovoltaic power collector comprising:
a plurality of air cooled solar photovoltaic modules electrically interconnected in series to form a solar photovoltaic power source having a solar photovoltaic power collector output capable of maintaining a peak DC voltage of at least 1,000 volts, each of the plurality of air cooled solar photovoltaic modules comprising:
a plurality of at least thirty linearly oriented solar cells electrically connected in series; and
a linearly oriented substrate, the plurality of at least thirty linearly oriented solar cells physically arranged substantially in a single row on a first side of the linearly oriented substrate, the linearly oriented substrate formed from a thermally conductive composition and having an expanded heat dissipation-to-ambient surface region on a second side of the linearly oriented substrate, the second side of the linearly oriented substrate opposing the first side of the linearly oriented substrate.

2. The solar photovoltaic power collector of claim 1 wherein each of the plurality of air cooled solar photovoltaic modules further comprises an interlock structural element for interlocking together the linearly oriented substrates for each of the plurality of air cooled solar photovoltaic modules.

3. The solar photovoltaic power collector of claim 2 further comprising a dielectric material disposed between the interlock structural elements of adjacent ones of the plurality of air cooled solar photovoltaic modules to electrically insulate adjacent ones of the plurality of air cooled solar photovoltaic modules.

4. The solar photovoltaic power collector of claim 1 further comprising a solar tracker, the solar photovoltaic power collector mounted on the solar tracker.

5. The solar photovoltaic power collector of claim 1 further comprising at least one electrical insulator for insulating the solar photovoltaic power collector from ground potential.

6. The solar photovoltaic power collector of claim 1 further comprising a step-up voltage regulator, the solar photovoltaic power collector and step-up voltage regulator arranged to form a step-up voltage regulated solar photovoltaic power collector having a step-up voltage regulated output.

7. The solar photovoltaic power collector of claim 1 further comprising a step-down current regulator, the solar photovoltaic power collector and step-down current regulator arranged to form a step-down current regulated solar photovoltaic power collector having a step-down current regulated output.

8. A solar photovoltaic power collection circuit having a solar photovoltaic power collection circuit output capable of maintaining a peak DC power level of at least one megawatt, the solar photovoltaic power collection circuit comprising:
a plurality of solar photovoltaic power collectors, each one of the plurality of solar photovoltaic power collectors comprising a plurality of air cooled solar photovoltaic modules electrically interconnected in series to form a collector solar photovoltaic power source having an output capable of maintaining a peak DC voltage of at least 1,000 volts, each of the plurality of air cooled solar photovoltaic modules comprising:
a plurality of at least thirty linearly oriented solar cells electrically connected in series; and
a linearly oriented substrate, the plurality of at least thirty linearly oriented solar cells physically arranged substantially in a single row on a first side of the linearly oriented substrate, the linearly oriented substrate formed from a thermally conductive composition and having an expanded heat dissipation-to-ambient surface region on a second side of the linearly oriented substrate, the second side of the linearly oriented substrate opposing the first side of the linearly oriented substrate.

9. The solar photovoltaic power collection circuit of claim 8 further comprising a separate step-up voltage regulator in combination with each one of the plurality of solar photovoltaic power collectors forming a step-up voltage regulated solar photovoltaic power collector having a step-up voltage regulated output, the step-up voltage regulated outputs of all step-up voltage regulated solar photovoltaic power collectors connected in parallel to form the output of the solar photovoltaic power collection circuit.

10. The solar photovoltaic power collection circuit of claim 9 further comprising a step-up voltage regulation circuit for each one of the separate step-up voltage regulators to independently maintain the step-up voltage regulated output at the maximum power point of the plurality of the linearly oriented solar cells in the plurality of air cooled solar photovoltaic modules in combination with the separate step-up voltage regulator.

11. The solar photovoltaic power collection circuit of claim 8 further comprising a separate step-down current regulator in combination with each one of the plurality of solar photovoltaic power collectors forming a step-down current regulated solar photovoltaic power collector having a step-down current regulated output, the step-down current regulated outputs of all step-down current regulated solar photovoltaic power collectors connected in series to form the output of the solar photovoltaic power collection circuit.

12. The solar photovoltaic power source of claim 11 further comprising a step-down current regulation circuit for each one of the separate step-up voltage regulators to independently maintain the step-down current regulated output at the maximum power point of the plurality of linearly oriented solar cells in the plurality of air cooled solar photovoltaic modules in combination with the separate step-down current regulator.

13. A method of generating DC electric power at least at a maintained peak voltage of 1,000 volts from a solar photovoltaic source, the method comprising the steps of:
forming each one of a plurality of linearly oriented air cooled solar photovoltaic modules from a plurality of at least thirty solar cells electrically connected in series and arranged in a single row on a thermally conductive linearly oriented substrate having an expanded heat dissipation-to-ambient surface region on the side of the thermally conductive linearly oriented substrate opposite the side of the thermally conductive linearly oriented substrate upon which the plurality of solar cells are arranged; and
electrically interconnecting the plurality of linearly oriented air cooled solar photovoltaic modules to form at least one solar photovoltaic power collector having a collector output for the generated DC electric power.

14. The method of claim 13 further comprising the steps of arranging the at least one solar photovoltaic power collector into at least two separate solar photovoltaic power collectors and electrically connecting the collector outputs of each one of the at least two separate solar photovoltaic power collectors in parallel.

15. The method of claim 13 further comprising the steps of arranging the at least one solar photovoltaic power collector into at least two separate solar photovoltaic power collectors, electrically connecting the collector outputs of each one of the at least two separate solar photovoltaic power collectors in parallel, and independently step-up voltage regulating the collector output of each one of the at least two separate solar photovoltaic power collectors.

16. The method of claim 15 further comprising the steps of inverting the generated DC electric power to AC electric power and injecting the AC electric power into an electric power transmission network, wherein the step of independently step-up voltage regulating the collector output of each one of the at least two separate solar photovoltaic power collectors has a regulation time period equal to a multiple of one-sixth of the electric power transmission network's line voltage time period.

17. The method of claim 13 further comprising the steps of arranging the at least one solar photovoltaic power collector into at least two separate solar photovoltaic power collectors, electrically connecting the collector outputs of each one of the at least two separate solar photovoltaic power collectors in series, and independently step-down current regulating the collector output of each one of the at least two separate solar photovoltaic power collectors.

18. The method of claim 17 further comprising the steps of inverting the generated DC electric power to AC electric power and injecting the AC electric power into an electric power transmission network, wherein the step of independently step-down current regulating the collector output of each one of the at least two separate solar photovoltaic power collectors has a regulation time period equal to a multiple of one-sixth of the electric power transmission network's line voltage time period.

19. The method of claim 13 further comprising the step of electrically arranging a plurality of the at least one solar photovoltaic power collector for the generated DC electric power to have a minimum peak output of one megawatt.

20. The method of claim 19 further comprising the steps of electrically connecting the collector outputs of each one of the plurality of the at least one solar photovoltaic power collector in parallel, and independently step-up voltage regulating the collector output of each one of the at least one solar photovoltaic power collectors.

21. The method of claim 20 wherein the step of independently step-up voltage regulating the collector output of each one of the plurality of the at least one solar photovoltaic power collector further comprises independently maintaining the collector output of each one of the plurality of the at least one power collector at the maximum power point of the plurality of solar cells in the plurality of air cooled solar photovoltaic modules in each one of the plurality of the at least one solar photovoltaic power collector.

22. The method of claim 21 further comprising the steps of inverting the generated DC electric power to AC electric power and injecting the AC electric power into an electric power transmission network, wherein the step of independently step-up voltage regulating the collector output of each one of the plurality of the at least one solar photovoltaic power collector has a regulation time period equal to a multiple of one-sixth of the electric power transmission network's line voltage time period.

23. The method of claim 19 further comprising the steps of electrically connecting the collector outputs of each one of the plurality of the at least one solar photovoltaic power collector in series, and independently step-down current regulating the collector output of each one of the plurality of the at least one solar photovoltaic power collectors.

24. The method of claim 23 wherein the step of independently step-down current regulating the collector output of each one of the plurality of the at least one photovoltaic power collector further comprises independently maintaining the collector output of each one of the plurality of the at least one power collector at the maximum power point of the plurality of solar cells in the plurality of air cooled solar photovoltaic modules in each one of the plurality of the at least one solar photovoltaic power collector.

25. The method of claim 24 further comprising the steps of inverting the generated DC electric power to AC electric power and injecting the AC electric power into an electric power transmission network, wherein the step of independently step-down voltage regulating the collector output of each one of the plurality of the at least one solar photovoltaic power collector has a regulation time period equal to a multiple of one-sixth of the electric power transmission network's line voltage time period.

26. A method of fabricating a linearly oriented air cooled solar photovoltaic module, the method comprising the steps of:
heating at least a seating surface on a thermally conductive linearly oriented substrate having an expanded heat dissipation-to-ambient surface region on the side of the linearly oriented substrate opposite the seating surface;
consecutively bonding a serially oriented array of at least thirty solar cells with interconnecting electrical conductors between two encapsulation layers to form a linear solar cell assembly; and
moving the thermally conductive linearly oriented substrate relative to the formed linear solar cell to lay the linear solar cell assembly along the seating surface as the linear solar cell assembly is formed.
